(19) United States
(12) Patent Application Publication
(10) Pub. No.: US 2011/0094681 A1
(43) Pub. Date: Apr. 28, 2011

(54) Device For Cleaning Objects

(75) Inventors: Michael Bisges, Sinzing (DE); Thorsten Krüger, Regensburg (DE); Patrick Wichmann, Petershagen (DE); Hans-Jürgen Arning, Lubbecke (DE)

(73) Assignee: Reinhausen Plasma GmbH, Regensburg (DE)

(21) Appl. No.: 13/002,285

(22) PCT Filed: Jun. 30, 2009
(86) PCT No.: PCT/EP2009/058184

§ 371 Date: Jan. 11, 2011

(30) Foreign Application Priority Data
Jul. 2, 2008 (DE) 20 2008 008 729.5
Dec. 23, 2008 (DE) 10 2008 063 050.0

(51) Int. Cl. H01L 21/306; B08B 5/02

(52) U.S. Cl. 156/345.26; 156/345.1; 156/345.4

(57) ABSTRACT

A device for cleaning objects includes, a device for drawing in surrounding air, a device for producing plasma and a device for blowing out a mixture of surrounding air and plasma into the object to be cleaned. The device is used preferably in household applications in the cleaning and sanitization of mattresses, joints and walls.

### PRIORITY CLAIM

This is a U.S. national stage of Application No. PCT/EP2009/058184, filed on Jun. 30, 2009, which claims priority to German Application No: 10 2008 063 050.0, filed: Dec. 23, 2008, and German Application No. 20 2008 008 729.5, filed Jul. 2, 2008 the contents of which are incorporated herein by reference.

### BACKGROUND OF THE INVENTION

1. Field of the Invention

The present invention pertains to a device for cleaning objects, especially mattresses.

2. Related Art

Vacuum cleaners are known that can be used to clean carpets, upholstered furniture, and mattresses. A vacuum cleaner, however, cannot neutralize odors, and it has only very limited ability to draw up germs and spores, which therefore remain in the textile material.

There are also wet cleaners, which have a certain sterilizing effect. These wet cleaners, however, act only on the surface and require a long drying time. The cleaning process is comparatively complicated, and care must be taken not to introduce too much moisture into the textile.

There are also UV lamps, which act on the surface and kill germs and spores located there. Such lamps cannot reach the area inside the textile, however, which means that their effectiveness is quite limited.

### SUMMARY OF THE INVENTION

A goal of the invention is to create a device that can be used to clean objects, especially mattresses, and which also makes deep-cleaning possible.

According to one embodiment of the invention, the device for cleaning objects comprises a mechanism for drawing in ambient air, a mechanism for generating plasma, and a device for blowing out a mixture of ambient air and plasma into the object to be cleaned. As a result, in addition to cleaning the surface of the object, the mixture of ambient air and plasma is also blown into the object, so that the cleaning effect also penetrates into the object to a certain depth. The plasma preferably contains ozone, so that germs and spores can be reliably killed. Cleaning of this type is very safe for materials and does not interfere with the use of the object by making it wet, for example. Nor is there any need for consumable chemicals.

According to a preferred embodiment of the invention, a housing is provided, on which at least one jet opening is arranged that is surrounded on all sides by a seal. The housing can comprise one or more jet openings in the bottom that are surrounded by the seal. A certain positive pressure can thus be built up, which makes possible an especially good deep-cleaning effect.

The mechanism for generating plasma comprises preferably at least one electrode at which an electrical discharge can be produced. The electrode can be installed in, and protected by, a housing, so that there is no safety hazard for the user. An appropriate power supply unit with a transformer can also be integrated into the device.

In another embodiment of the invention, a blower is provided to draw in ambient air and to blow out the mixture of ambient air and plasma. The blower can be provided in the flow path at least one of upstream and downstream of the mechanism for generating plasma. The cross section of the flow path can be selected to be comparatively small in the area of the blower, so that a high flow velocity is present there, whereas the cross section in the area of the mechanism for generating plasma is larger, so that a somewhat slower flow velocity is obtained.

A pressure sensor is preferably provided, by which it is possible to detect positive pressure in an area of the outlet. A control unit can also be provided, by which the blower can be regulated automatically as a function of the detected pressure. For example, when the flow resistance is high, the pressure which is produced is also high; in such cases, the blower can be operated at higher rpm's in order to guarantee a deep-cleaning effect in the textile.

In a preferred embodiment of the invention, the mechanism for generating plasma comprises a molded body, on which at least one discharge electrode and at least one coupling electrode are capacitively coupled to each other. As a result, the mechanism for producing plasma can be installed in the form of a module in the housing. The molded body can comprise a plurality of air channels, through which ambient air flows, so that the plasma which has been generated can be effectively mixed and transported further along.

To prevent the mixture of plasma and ambient air from escaping on one side, the seal can be designed as an elastic rubber sealing strip that forms a seal against the textile around all sides, so that a certain positive pressure is maintained for the blowing-in of the mixture.

The mechanism for generating plasma preferably comprises a plurality of piezoelectric elements, which ensures a compact design.

So that the device can be handled easily, a handle for guidance, which allows the device to be moved easily over the object to be cleaned, can be provided on the housing.

It is also advantageous for the plasma cleaning arrangement to be combined with a device for mechanical cleaning. Precisely when cleaning areas which are highly contaminated with germs such as joints or when mold has formed on walls, the surface in question can thus be cleaned more effectively. The mechanical cleaning device can be designed in the form of a brush, a sponge, or a scouring pad on the bottom of the device, which rests on the surface to be cleaned.

Because, during the cleaning of narrow gaps and joint surfaces, there is often not enough room to allow the mechanical cleaning of the surface in addition to the plasma cleaning, the invention is provided, in accordance with a preferred embodiment, a mechanical drive, which causes the cleaning device to execute preferably rotating or oscillating movements.

To guarantee optimal cleaning effects and a certain depth of cleaning penetration, the material of the brush, of the sponge, or of the scouring pad comprises gas-permeable pores, as a result of which the plasma particles are conducted to the surface to be cleaned.

For the cleaning of very dirty surfaces in restricted areas such as joints, a tubular design of the housing is advantageous. The dimensions of the housing are preferably such that the ratio of length to diameter is in the range of 3:1-20:1.

### BRIEF DESCRIPTION OF DRAWINGS

The invention is explained in greater detail below based on several exemplary embodiments, which are described in reference to the attached drawings in which:

FIGS. 1(a) and 1(b) show two views of a first exemplary embodiment of an inventive device for cleaning objects;

FIG. 2 is a cross-sectional side view of the device of FIGS. 1(a) and 1(b);

FIG. 3 is a cross-sectional side view of a modified device for cleaning objects;

FIGS. 4(a) and 4(b) are two cross-sectional side views of additional inventive devices for cleaning objects; and

FIGS. 5(a)-5(c) are three cross-sectional side views of modified devices for cleaning objects.

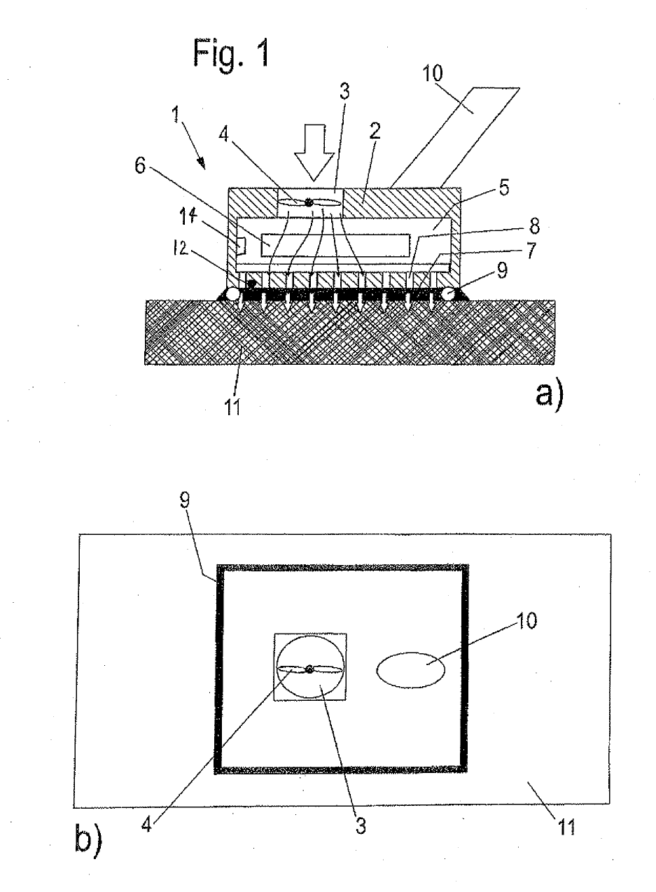

### DETAILED DESCRIPTION OF THE DRAWINGS

A device 1 for cleaning objects comprises a housing 2, in which a suction opening 3 for drawing in ambient air is provided. A blower 4, shown schematically, is also provided to draw in the ambient air and to blow it into a chamber 5, in which a mechanism 6 for generating plasma is installed. The indrawn air mixes in the chamber 5 with the ozone-containing plasma that has been generated and is then blow out at the bottom 7 of the housing 2 through a plurality of jet openings 8 in the bottom 7 of the housing. Underneath the bottom 7 a space is formed, which is bounded around the edges by a peripheral seal 9 in the form of an elastic rubber strip. Thus the space underneath the bottom 7 is sealed off, so that the blown-out mixture of ambient air and plasma can be directed under positive pressure into the object 11 to be cleaned. The object 11 can be in particular a mattress, a carpet, a piece of upholstered furniture, etc.

So that the housing 2 can be guided along the object 11 to be cleaned, a projecting handle 10 is provided, which makes it easy to maneuver the device. Via the handle 10, the housing 2 with the seal 9 can be pressed against the object 11 to be cleaned to produce a sealing effect.

A pressure sensor 12, by which the positive pressure in the area of the jet openings 8 underneath the bottom 7 can be detected, can also be provided in the housing 2. This pressure sensor 12 is connected to a control unit 14, which controls the blower 4. A high positive pressure means that the flow resistance through the object 11 is high; as a result, the blower 4 can be operated with greater power to ensure the deep-cleaning of the object 11.

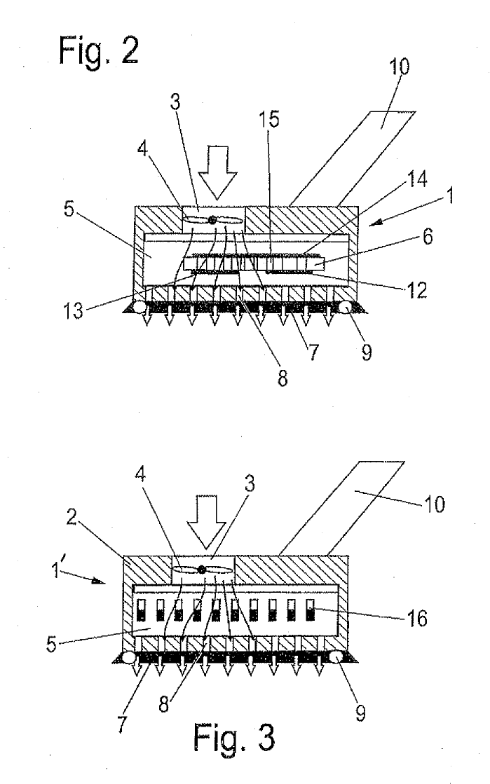

FIG. 2 shows a cross section of the device 1, wherein the mechanism 6 for generating plasma is shown in the chamber 5. The mechanism comprises a molded body, which has two coupling electrodes 12 and 13 on one side, which are coupled capacitively with a discharge electrode 14, which is mounted on the opposite side of the molded body. The electrodes 12, 13 are connected to a power supply unit, which is responsible for creating a discharge at the discharge electrode 14 at a suitable voltage and frequency, so that ozone-containing plasma is formed. This plasma mixes with the indrawn air in the chamber 5. It is also possible to provide several of these molded bodies or several sets of electrodes 12, 13, 14 to increase the quantity of plasma. Air channels 15 are also formed in the molded body, so that the air can mix even more effectively with the generated plasma. The mixture of ambient air and plasma then leaves the chamber 5 through the air channels 8 in the bottom.

FIG. 3 shows a modified embodiment of a device 1′, in which a chamber 5 is again formed in the housing 2; in this case, a plurality of piezoelectric elements 6′ is arranged in the chamber to generate the plasma. The indrawn air is blown into the chamber 5 by the blower 4 and leaves through the bottom of the housing 2. The number of piezoelectric elements 16 is adapted to the volume flow rate of the indrawn air.

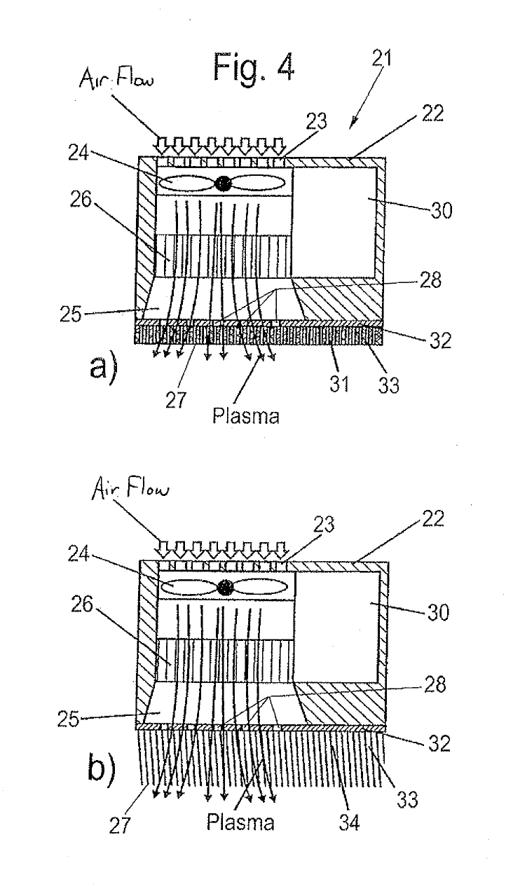

FIG. 4(a) shows a modified device 21, which combines the cleaning effect achieved through the generation of plasma with mechanical cleaning. The device 21 has a suction opening 23 in a housing 22 and a blower 24, which is responsible for providing a continuous supply of ambient air and for carrying away the plasma, which thus prevents the concentration of plasma from increasing too much.

A control unit for the blower 24 can be used to adjust the rate at which the indrawn ambient air flows into the housing 22. The air is converted into an ozone-containing plasma/air mixture at the mechanism 26 for plasma generation in a chamber 25. The mechanism for plasma generation 26 is connected to an internal energy storage unit 30. An external power supply/storage unit is also possible.

The air/plasma mixture emerges from the housing 22 at the bottom side 27 of the device 21. A scouring pad 31, which is fastened by a layer of adhesive or Velcro® tape 32 to the housing 22, can be used to clean dead biological material from a surface. The scouring pad 31 comprises gas channels 33, through which the plasma/air mixture flows.

FIG. 4(b) shows another variant of the device with a mechanical cleaning device. All of the components are designed in the same way as those described in FIG. 4(a) except for the mechanical cleaning device, which here is in the form of a brush 34. It is fastened to the housing 22 by a layer of adhesive or Velcro® 32 tape. The bristles of the brush have gas channels 33.

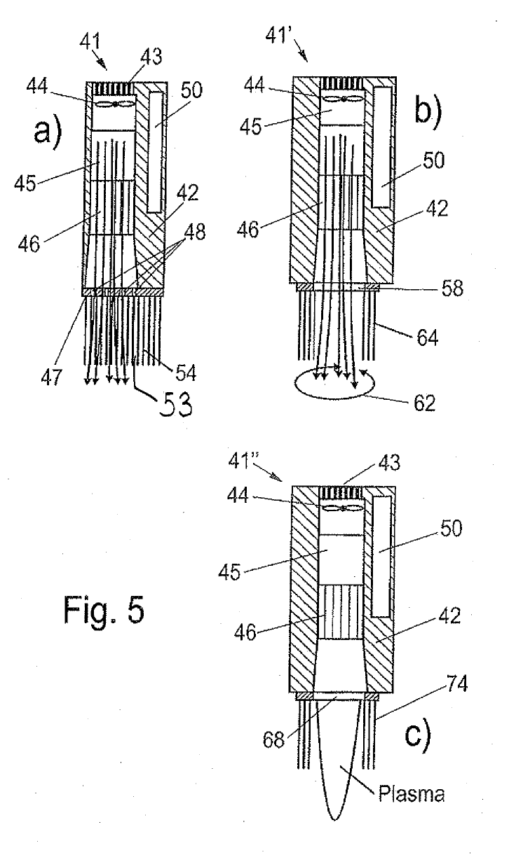

FIG. 5(a) shows an inventive device 41, in which a housing 42 is designed in the form of a tube and which is therefore especially suitable for the cleaning of joints and corners. Through a suction opening 43, ambient air is drawn into a chamber 45 by a blower 44. The flow velocity thus produced is regulated by a control unit for the blower 44. A mechanism 46 for generating plasma then converts some of the ambient air into plasma. At the bottom side 47 of the housing 42, jet openings 48 are provided, through which a delivery of the air/plasma mixture to a surface to be cleaned takes place.

A brush 54 is attached to the bottom side 47 of the housing 42. The brush has bristles with gas channels 53. The power is supplied by batteries 50, which are integrated into the housing 42 of the device.

FIG. 5(b) shows a modification 41′ of the device in FIG. 5(a). A brush 64 is shown schematically on the periphery of jet opening 58. The brush executes rotating or oscillating movements, as indicated by the arrow 62. The outlet 58 is wider than in the preceding example to increase the output of the plasma/air mixture.

FIG. 5(c) shows another modification 41″ of the device of FIG. 5(a), wherein a stationary brush 74 is installed around the periphery of the jet opening 68. The width of the jet opening 68 makes it possible for the emerging plasma/air mixture to have a laminar flow profile and thus for the plasma stream to be concentrated into a “bundle”.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A device for cleaning objects, comprising:
a mechanism for drawing in ambient air;
a mechanism for generating plasma; and
an apparatus configured to blow out a mixture of the ambient air and the plasma into the object to be cleaned.

17. The device according to claim 16, wherein the apparatus comprises a housing with at least one jet opening arranged on an exit side of the housing configured to blow out the mixture of the ambient air and the plasma into the object to be cleaned; and
a seal affixed to the housing configured to surround the at least one jet opening.

18. The device according to claim 17, wherein the mechanism for generating plasma comprises at least one electrode configured to generate an electrical discharge.

19. The device according to claim 17, wherein the mechanism for drawing in ambient air comprises a blower configured to draw in the ambient air and for blowing out the mixture of the ambient air and the plasma.

20. The device according to claim 19, further comprising a pressure sensor arranged proximate the at least one jet opening and configured to detect a pressure in an area of the jet opening.

21. The device according to claim 20, further comprising a control unit configured to automatically regulate the blower as a function of the detected pressure.

22. The device according to claim 16, wherein the mechanism for generating plasma comprises:
a molded body;
at least one discharge electrode arranged on the molded body; and
at least two coupling electrodes capacitively coupled to the at least one discharge electrode.

23. The device according to claim 22, wherein a plurality of air channels are provided in the molded body through which the mixture of the ambient air and the plasma flows.

24. The device according to claim 17, wherein the seal is an elastic rubber sealing strip.

25. The device according to claim 16, wherein the mechanism for generating plasma comprises a plurality of piezoelectric elements.

26. The device according to claim 17, further comprising a handle on the housing configured to guide the device over the object to be cleaned.

27. The device according to claim 17, further comprising a cleaning device for mechanical cleaning on the exit side of the housing.

28. The device according to claim 27, further comprising a drive configured to set the cleaning device in motion.

29. The device according to claim 27, wherein cleaning device comprises at least one of gas-permeable pores and channels.

30. The device according to claim 17, wherein the housing is tubular with a length-to-ratio ratio in the range of 3:1-20:1.

31. The device according to claim 27, wherein the cleaning device comprises at least one of a brush, a sponge, and a scouring pad.

32. The device according to claim 31, wherein cleaning device comprises at least one of gas-permeable pores and channels.

33. The device according to claim 32, wherein the housing is tubular with a length-to-ratio ratio in the range of 3:1-20:1.
